(19) United States
(12) Patent Application Publication
(10) Pub. No.: US 2009/0150103 A1
(43) Pub. Date: Jun. 11, 2009

(54) Computer-Based Method and System for Simulating Static Timing Clocking Results

(76) Inventors: Matthew Roger Ellavsky, Rochester, MN (US); Brandon E. Schenck, Rochester, MN (US); Jing Zhang, Austin, TX (US)

Correspondence Address: IBM CORPORATION, 3605 HIGHWAY 52 NORTH, DEPT 917, ROCHESTER, MN, 55901-7829, US

(21) Appl. No.: 11/951,593

(22) Filed: Dec. 6, 2007

(51) Int. Cl. G01R 29/02

(52) U.S. Cl. 702/79

(57) ABSTRACT

A method, system and computer-readable medium are presented for creating unique clock waveform checking commands for an event simulator to validate that the logical creation matches the timing definitions. The method includes selecting one or more clock signals for validation; specifying timing definitions of the selected clock signals; automatically categorizing the selected clock signals based on their synchrony; automatically matching each selected clock signal to a corresponding clock cycle by parsing the specified timing definitions; specifying one or more test cases for an event simulator, wherein the test cases simulate logic for generating each selected clock signal; validating that the logic for generating each selected clock signal matches the specified timing definitions for each selected clock signal.

### BACKGROUND OF THE INVENTION

1. Technical Field of the Invention

The present invention relates in general to the field of computers, and in particular to computer-based tools for electronic design automation.

2. Description of the Related Art

High-performance integrated circuits have traditionally been characterized by the clock frequency at which they operate. Gauging the ability of a circuit to operate at the specified speed requires the ability to measure, during the design process, the circuit delay at numerous steps. Moreover, delay calculation must be incorporated into the inner loop of timing optimizers at various phases of design, such as logic synthesis, layout (placement and routing), and in in-place optimizations performed late in the design cycle. While such timing measurements can theoretically be performed using a rigorous circuit simulation, such an approach is usually too slow to be practical. Static timing analysis is a method of computing the expected timing of a digital circuit without requiring circuit simulation. Static timing analysis plays a vital role in facilitating the fast and reasonably accurate measurement of circuit timing. Static timing analysis has become a mainstay of design over the last few decades.

In a synchronous digital system, data is supposed to move in lockstep, advancing one stage on each tick of the clock signal. The synchronous movement of data is enforced by synchronizing elements such as flip-flops or latches, which copy their input to their output when instructed to do so by the clock. The time when a signal arrives can vary due to many reasons—the input data may vary, the circuit may perform different operations, the temperature and voltage may change, and there are manufacturing differences in the exact construction of each part. The main goal of static timing analysis is to verify that despite these possible variations, all signals will arrive neither too early nor too late, thereby assuring a designer of proper circuit operation.

Accurately mapping the logical formation of a clock into definitions for a static timing tool increases in complexity as the logical formation increases in complexity. Static timing tools are not fully logic aware, and are unable to automatically map clock generation structures into proper timing definitions which match the logical formation. As a result, designers are required to manually code timing definitions in a way that matches how the logic was created. Mistakes made during this manual coding process can result in design errors that will not be detected by timing analysis or by simulation.

### BRIEF SUMMARY OF THE INVENTION

The present invention provides a method, system and computer-readable medium for automatically importing results from a static timer and creating unique clock waveform checking commands for an event simulator to validate that the logical creation matches the timing definitions. In one embodiment, the method includes selecting one or more clock signals for validation; specifying timing definitions of the selected clock signals; automatically categorizing the selected clock signals based on their synchrony; automatically matching each selected clock signal to a corresponding clock cycle by parsing the specified timing definitions; specifying one or more test cases for an event simulator, wherein the test cases simulate logic for generating each selected clock signal; validating that the logic for generating each selected clock signal matches the specified timing definitions for each selected clock signal.

The above, as well as additional purposes, features, and advantages of the present invention will become apparent in the following detailed written description.

### BRIEF DESCRIPTION OF THE SEVERAL VIEWS OF THE DRAWINGS

The novel features believed characteristic of the invention are set forth in the appended claims. The invention itself, however, as well as a best mode of use, further purposes and advantages thereof, will best be understood by reference to the following detailed description of an illustrative embodiment when read in conjunction with the accompanying drawings, where:

FIG. 1 shows a block diagram of an exemplary data processing system in which the present invention may be implemented;

FIG. 2 shows an exemplary integrated circuit logic 200 and corresponding timing waveforms 208 depicting prior art manual timing definitions;

FIG. 3 shows a block diagram of an exemplary embodiment of the present invention;

FIG. 4 shows a flowchart 400 depicting an exemplary method for simulating static timing clocking results in accordance with one or more embodiments of the present invention; and

FIG. 5 shows flowchart 500 depicts an exemplary method for performing the validating step 414 of FIG. 4, in accordance with one or more embodiments of the present invention.

### DETAILED DESCRIPTION OF THE INVENTION

An illustrative embodiment of the present invention is directed to a method, system and computer-readable medium for creating unique clock waveform checking commands for an event simulator to validate that the logical creation matches the timing definitions. The present invention can take the form of an entirely hardware embodiment, an entirely software embodiment or an embodiment containing both hardware and software elements. In an illustrative embodiment, the invention is implemented in software, which includes, but is not limited to, firmware, resident software, microcode, etc.

Furthermore, the invention can take the form of a computer program product accessible from a computer-usable or computer-readable medium providing program code for use by or in connection with a computer or any instruction execution system. For the purposes of this description, a computer-usable or computer-readable medium can be any apparatus that can contain, store, communicate, propagate, or transport the program for use by or in connection with the instruction execution system, apparatus or device.

The medium can be an electronic, magnetic, optical, electromagnetic, infrared or semiconductor system, apparatus or device or a propagation medium. Examples of a computer-readable medium include a semiconductor or solid state memory (e.g., flash drive memory), magnetic tape, a removable computer diskette, a random access memory (RAM), a read-only memory (ROM), a rigid magnetic disk (e.g., a hard drive) and an optical disk. Current examples of optical disks include compact disk—read only memory (CD-ROM), compact disk—read/write (CD-R/W) and Digital Versatile Disk (DVD).

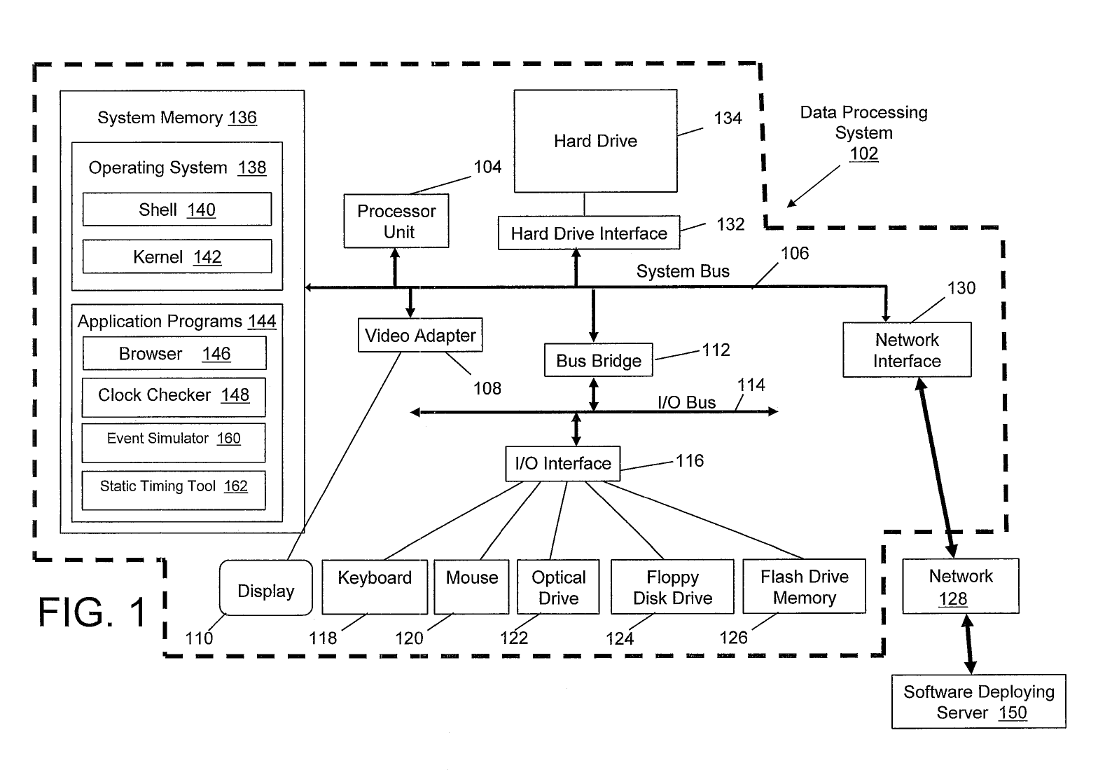

Referring now to the drawings, wherein like numbers denote like parts throughout the several views, FIG. 1 shows a block diagram of a data processing system suitable for storing and/or executing program code in accordance with one or more embodiments of the present invention. The hardware elements depicted in data processing system 102 are not intended to be exhaustive, but rather are representative of one embodiment of the present invention. Data processing system 102 includes a processor unit 104 that is coupled to a system bus 106. A video adapter 108, which drives/supports a display 110, is also coupled to system bus 106. System bus 106 is coupled via a bus bridge 112 to an Input/Output (I/O) bus 114. An I/O interface 116 is coupled to I/O bus 114. I/O interface 116 affords communication with various I/O devices, including a keyboard 118, a mouse 120, an optical disk drive 122, a floppy disk drive 124, and a flash drive memory 126. The format of the ports connected to I/O interface 116 may be any known to those skilled in the art of computer architecture, including but not limited to Universal Serial Bus (USB) ports.

Data processing system 102 is able to communicate with a software deploying server 150 via a network 128 using a network interface 130, which is coupled to system bus 106. Network 128 may be an external network such as the Internet, or an internal network such as an Ethernet or a Virtual Private Network (VPN). Software deploying server 150 may utilize a similar architecture design as that described for data processing system 102.

A hard drive interface 132 is also coupled to system bus 106. Hard drive interface 132 interfaces with hard drive 134. In an illustrative embodiment, hard drive 134 populates a system memory 136, which is also coupled to system bus 106. Data that populates system memory 136 includes an operating system (OS) 138 of data processing system 102 and application programs 144.

OS 138 includes a shell 140, for providing transparent user access to resources such as application programs 144. Generally, shell 140 is a program that provides an interpreter and an interface between the user and the operating system. More specifically, shell 140 executes commands that are entered into a command line user interface or from a file. Thus, shell 140 (as it is called in UNIX®), also called a command processor in Windows®, is generally the highest level of the operating system software hierarchy and serves as a command interpreter. The shell provides a system prompt, interprets commands entered by keyboard, mouse, or other user input media, and sends the interpreted command(s) to the appropriate lower levels of the operating system (e.g., a kernel 142) for processing. Note that while shell 140 is a text-based, line-oriented user interface, the present invention will equally well support other user interface modes, such as graphical, voice, gestural, etc.

As depicted, OS 138 also includes kernel 142, which includes lower levels of functionality for OS 138, including providing essential services required by other parts of OS 138 and application programs 144, including memory management, process and task management, disk management, and mouse and keyboard management. An exemplary OS 138 in accordance with an embodiment of the present invention is one of the Advanced Interactive eXecutive (AIX®) operating systems from IBM Corporation.

Application programs 144 include a browser 146. Browser 146 includes program modules and instructions enabling a World Wide Web (WWW) client (i.e., data processing system 102) to send and receive network messages to the Internet using HyperText Transfer Protocol (HTTP) messaging, thus enabling communication with software deploying server 150. Application programs 144 also include electronic design automation tools (EDA) such as Event Simulator 160 and Static Timing Tool 162. Event Simulator 160 is an application program for simulating integrated circuit designs, such as Cadence® NC-VHDL, a registered trademark of Cadence Design Systems, Inc. In one embodiment, Event Simulator 160 is capable of performing test cases encoded in a Tool Command Language (Tcl). Static Timing Tool 162 is an application program for performing static timing analysis on an integrated circuit design.

Application programs 144 in the system memory of data processing system 102 (as well as the system memory of software deploying server 150) also include Clock Checker 148. Clock Checker 148 comprises computer-executable code, at least a portion of which implements the method described herein. Clock Checker 148 may reside in system memory 136, as shown, and/or may be stored in non-volatile bulk storage such as hard drive 134. In one embodiment, data processing system 102 is able to download Clock Checker 148 from software deploying server 150.

The hardware elements depicted in data processing system 102 are not intended to be exhaustive, but rather are representative to highlight essential components required by the present invention. For instance, data processing system 102 may include alternate memory storage devices such as magnetic cassettes, Digital Versatile Disks (DVDs), Bernoulli cartridges, and the like. These and other variations are intended to be within the spirit and scope of the present invention.

Note further that, in one embodiment of the present invention, software deploying server 150 performs all of the functions associated with the present invention (including execution of Clock Checker 148), thus freeing data processing system 102 from having to use its own internal computing resources to execute Clock Checker 148.

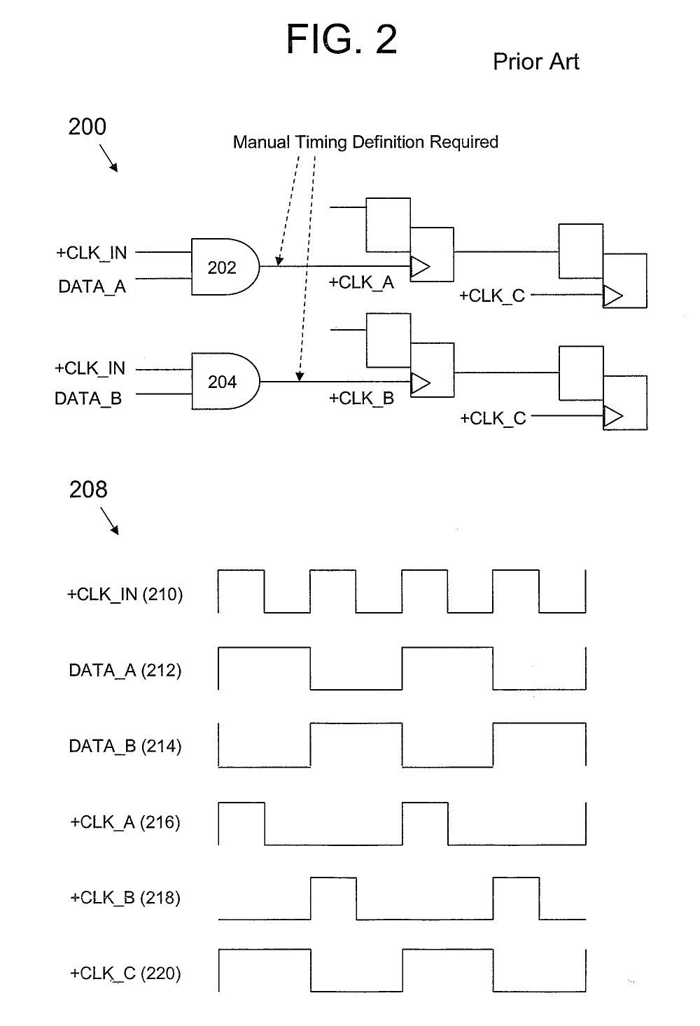

With reference now to FIG. 2, exemplary integrated circuit logic 200 and corresponding timing waveforms 208 are shown depicting prior art manual timing definitions. Waveforms 210, 212 and 214 correspond to signals CLK_IN, DATA_A and DATA_B respectively and are logically correct with matching correct timing definitions. Waveforms 216 and 218 correspond to signals CLK_A and CLK_B respectively and are logically correct. As the outputs of gates 202 and 204, CLK_A and CLK_B require manual timing definitions for static timing analysis. If, for example, an incorrect timing assertion were placed on the CLK_B output so that waveform 218 incorrectly matched waveform 216, then static timing analysis would time paths between CLK_B and CLK_C with the incorrect assumption that there is one full CLK_C cycle of setup slack available. However, there should actually be only one-half CLK_C cycle of setup slack available. This situation would lead to static timing violations that do not get reported. Additionally, neither cycle simulation nor event simulation would flag the CLK_B mis-alignment as a logical issue. Because of the zero delay nature of simulation, data will properly launch and capture the same between CLK_A and CLK_C and between CLK_B and CLK_C.

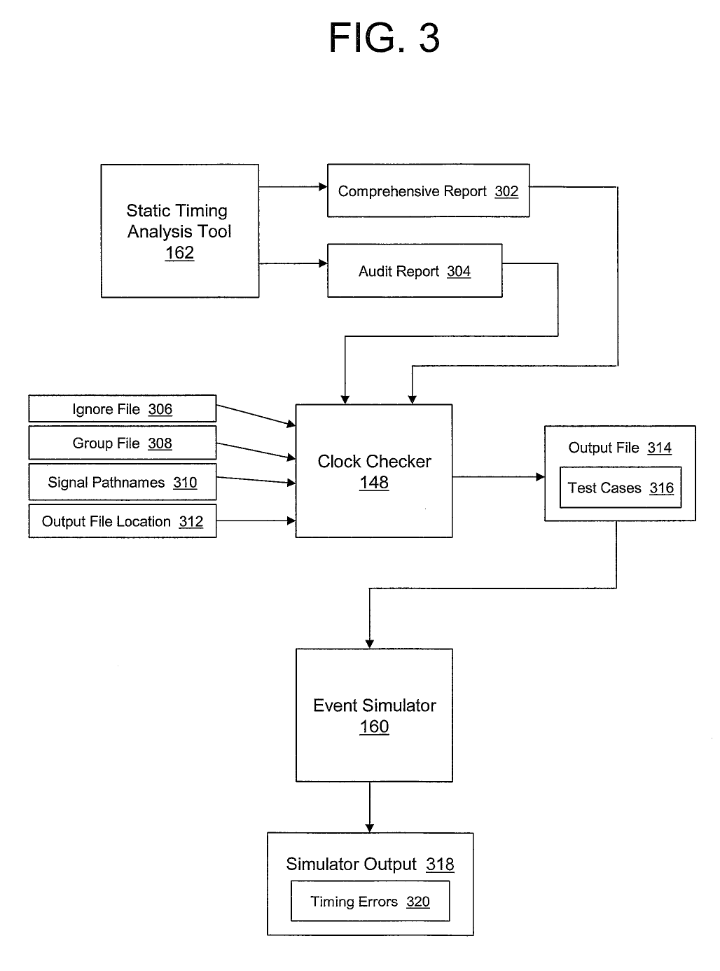

With reference now to FIG. 3, a block diagram is shown depicting an exemplary embodiment of the present invention. Clock Checker 148 is an electronic design automation tool that will test the logical behavior of a series of clocks against the phase definition (static timing clock rise/fall/cycle definition) for each clock. Clock Checker 148 does this by parsing the phase definitions of the selected clocks and writing out a series of checks that can be input to event simulator 160. In one embodiment, the checks are input to event simulator 160 as test cases 316. Test cases 316 are then run as normal in event simulator 160 and the clocks are checked on every clock rising/falling edge in the simulation window (either a real edge or where an edge should be). Simulation flags an error if a clock is found that does not match its phase definition. The checks include pulse-width, cycle time and alignment to other synchronous clocks.

Clock Checker 148 tests input/output signals against their definitions in the phase file, as well as alignments against each other. In one embodiment, Clock Checker 148 is written in Practical Extraction and Report Language (PERL) and produces output file 314 written in Tcl. Output file 314 contains test cases which are fed into event simulator 160. The output from event simulator 160 is stored in a file (simulator output 318) called “clock_checker.transcript” in a user-defined directory where all outputs (e.g., ncsim.log, ncsim.key) from the simulator reside. Simulator output 318 includes any timing errors 320 that occurred during simulation.

Clock Checker 148 automatically categorizes all signals based on their synchrony. Clock Checker 148 assumes that the user will specify initial values for certain signals (simplest user test case) which leads to the consistent toggling of all input/output signals. The intial value gets some of the clocks started and, since a static timing environment is being simulated, the clocks should not change from that initial behavior in the simulation window. Since Clock Checker 148 only checks one cycle of the longest cycle in each category (the reference cycle), it is important for the user to input output file 314 after the initial setup stage. Clock Checker 148 assumes that when a specific reference signal turns to 1, all signals behave normally. If so, output file 314 can be fed into the simulator at any time; if not, the user must make sure that all signals are ready before inputting output file 314. In addition, a test case 316 must run long enough to allow for at least one cycle of each signal. All test cases 316 (breakpoints in the simulator) in each category will automatically delete themselves after one cycle of the slowest clock in that category. Clock Checker 148 takes six arguments: comprehensive report 302, audit report 304, ignore file 306, group file 308, path name for signals 310, and the location of the output file 312.

Static timing tool 162 generates timing reports after performing a static timing analysis of an integrated circuit design. An example of static timing tool 162 is EinsTimer™ by IBM Corporation, which generates a comprehensive report 302 and an audit report 304. Comprehensive report 302 is used to map a phase to each clock's primary output (PO) and primary input (PI). Audit report 304 is used to determine how each phase is defined (typically under the section “et::create_clock”). Together they match each signal to the rising and falling edges of its clock cycle. The data extracted from these reports is generic across other static timing tools. The data can also be extracted directly from system memory 136 after static timing tool 162 completes its analysis.

Ignore file 306 allows the user to take out phases or signals that are not supposed to be tested. The file includes two sections: phase and signal (pin). For every phase listing in the “ignore these phases” section, its matching signals are also ignored. Listed signals are ignored without affecting its matching phase. The ignore file can be left blank.

Clock checker 148 automatically categorizes signals, but some signals that are seemingly synchronous by their cycles times may actually be asynchronous. Group file 308 allows a user to take out phases that are not supposed to be tested with the rest of the phases (e.g., asynchronous phases). Once a phase is taken out, the user is responsible for putting all phases that are synchronous with it in the same group. If a phase in group file 308 is determined to be invalid (e.g., in the ignore file or not being used by any signal), an error message is displayed to the user and the entire group (not the group file) that contains this phase is ignored. It is recommended for users to fix this problem before proceeding. Groups do not need to be in order. Signals with phases in group file 308 are also tested for accuracy and alignments. Group file 308 can be left blank. It may take a couple of simulation runs to complete an effective group file. If there are a large number of failures with a particular reference signal, the user should check the corresponding reference phase first for asynchrony and put it in a group if necessary. Group file 508 provides a way to manage exceptions.

Signal pathnames 310 are required for event simulator 160 to identify each signal. Output file location 312 directs event simulator 160 to the location of output file 314. There is a Tcl command “open” at the beginning of output file 314 to specify the location of the simulator output file (the default is relative to the current directory).

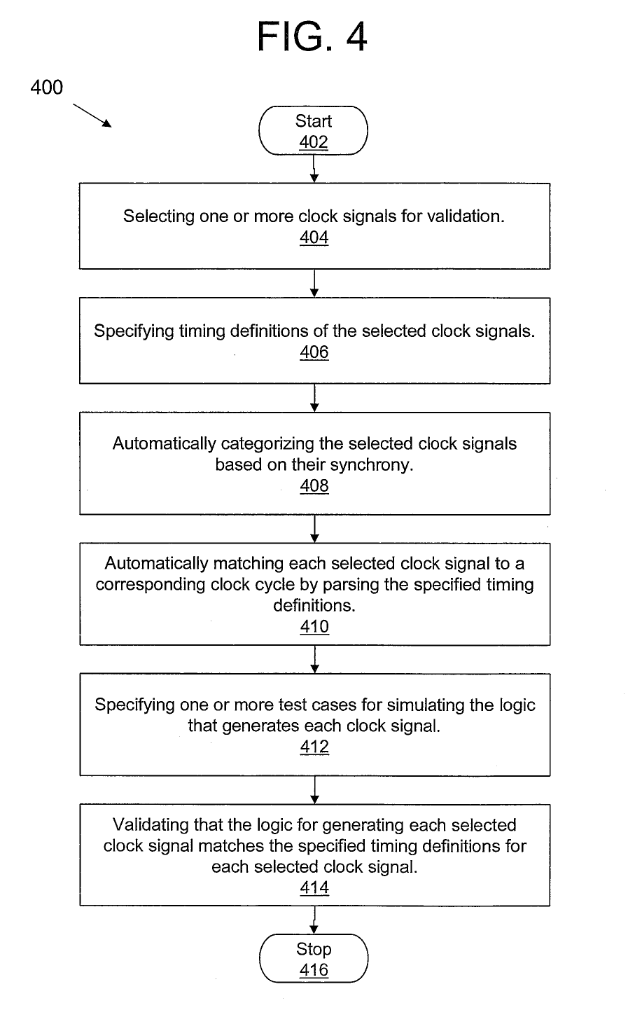

With reference now to FIG. 4, flowchart 400 depicts an exemplary method for simulating static timing clocking results in accordance with one or more embodiments of the present invention. The method begins at initiator block 402. Clock Checker 148 selects one or more clock signals for validation (step 404). In one embodiment, Clock Checker 148 tests the primary input and primary output signals in comprehensive report 302 from static timing tool 162. For example, using a comprehensive report generated by EinsTimer™, only signals with clock phases that end in a plus or minus sign (±) are selected. Phases ending in @L or @T correspond to data signals and are ignored. Input/output signals are then checked against ignore file 306 (both pins and phases). If a signal has multiple phases and one of its phases is in ignore file 306, the phase will be ignored but the signal is still valid as long as it has at least one valid phase. When a signal has multiple valid phases, Clock Checker 148 automatically selects the first phase it encounters, discards the rest and displays a warning message to the user. It is recommended that the user fix this problem (e.g., generating a new comprehensive report).

Clock Checker 148 specifies timing definitions for the selected clock signals (step 406). In one embodiment, Clock Checker 148 imports the timing definitions from static timing tool 162. The timing definitions are imported from output reports from static timing tool 162, such as comprehensive report 302 and audit report 304.

Clock Checker 148 automatically categorizes the selected clock signals based on their synchrony (step 408). In one embodiment, all valid signals are categorized, except for the signals specified in group file 308. A reference cycle is the longest cycle in each category. A reference signal is a signal having the reference cycle. A reference point is the time in the simulator when all tests start for one category. For example, a reference point is the time when CLKS_ALL_ON turns to 1 and the reference signal turns to 0, plus the difference between the cycle time and the falling edge of the reference signal equal to the reference point. If the reference point is not at a rising or falling edge but should be, the user should measure the cycle time of the reference signal on the waveform and compare it to the definition.

If the reference cycle time is an integer multiple of another cycle time, then signals of these two cycle times are synchronous to each other and are in the same category. Categorization is used to test alignment. If all signals in each category start at the same time and match their phase definitions, then alignments at proper edges are guaranteed.

Clock Checker 148 automatically matches each selected clock signal to a corresponding clock cycle by parsing the specified timing definitions (step 410). In one embodiment, Clock Checker 148 parses the timing definitions in comprehensive report 302 and audit report 304 to match each signal with the rising and falling edges of their corresponding cycle times. Any signal in comprehensive report 302 that has no corresponding phase is discarded.

Clock Checker 148 specifies one or more test cases for event simulator 160 to simulate the logic that generates each clock signal (step 412). The test cases are used to test the behavior of signals in the simulated waveform against the definition of the signals in comprehensive report 302 and audit report 304. In one embodiment, Clock Checker 148 generates output file 314, including test cases 316, which can be input to event simulator 160. Test cases 316 are run as normal simulations and the clocks are checked at every edge (expected or not), based on their phase definitions. Event simulator 160 validates that the logic for generating each selected clock signal matches the specified timing definitions for each selected clock signal (step 414). The method ends at terminator block 416.

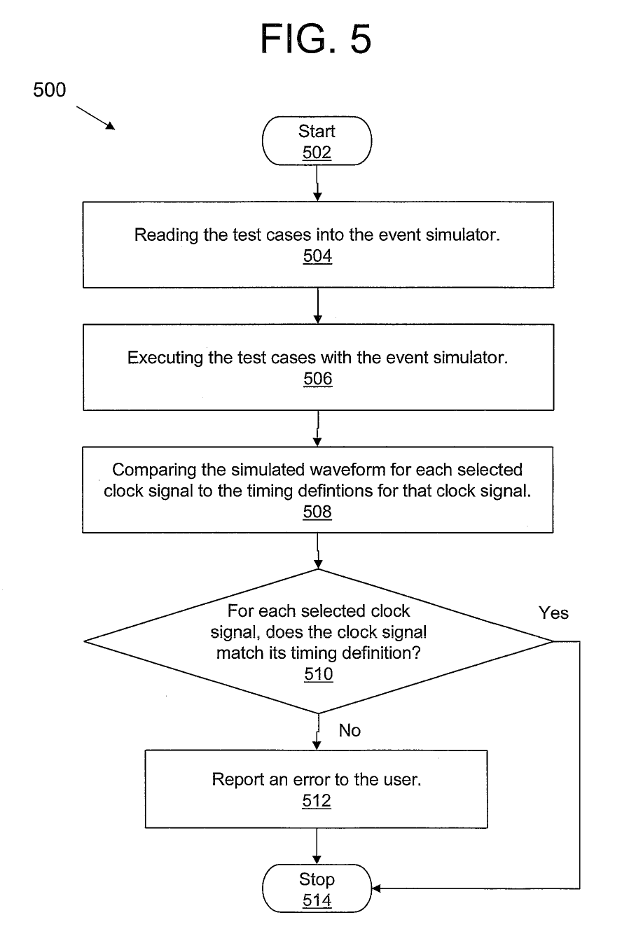

With reference now to FIG. 5, flowchart 500 depicts an exemplary method for performing the validating step 414 of FIG. 4, in accordance with one or more embodiments of the present invention. The method starts at initiator block 504. Event simulator 160 reads in output file 314, including test cases 316 (step 504). In one embodiment, there are two test cases 316 for each signal. One test case is for the rising edge of the clock cycle and one test case is for the falling edge of the clock cycle. Event simulator 160 executes the simulations for the test cases (step 506). All test cases (breakpoints in the simulator) in each category will automatically delete themselves after one cycle of the slowest clock in that category. Event simulator compares the simulated waveform for each selected clock signal to the timing definitions for that clock signal (step 508). If the signal value in event simulator 160 is incorrect within the specified time frame (step 510), timing error 320 is reported to the user (step 512). For example, timing error 320 may be recorded in simulator output file 318. The time frame is defined according to the signals' rising and falling edges.

This application not only checks the signal value within certain time frames against the specified definition of the signal (e.g., pulse width, cycle time), but also checks alignments among signals within each category. Since all signals in a category are synchronous and the reference signal has the longest cycle time, when the reference signal begins a cycle, all other signals in this category begin their cycles at the same time. If all signals begin at the same time and follow their phase definitions, the alignments at other edges are also guaranteed.

While the present invention has been particularly shown and described with reference to an illustrative embodiment, it will be understood by those skilled in the art that various changes in form and detail may be made therein without departing from the spirit and scope of the invention. Furthermore, as used in the specification and the appended claims, the term “computer” or “computer system” or “computing device” includes any data processing system including, but not limited to, personal computers, servers, workstations, network computers, mainframe computers, routers, switches, Personal Digital Assistants (PDA's), telephones, and any other system capable of processing, transmitting, receiving, capturing and/or storing data. The term “system” or “information system” includes a network of data processing systems.

Flowcharts and diagrams in the Figures illustrate the architecture, functionality, and operation of possible implementations of systems, methods and computer program products according to various embodiments of the present invention. In this regard, each block in the flowchart or diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

Having thus described the invention of the present application in detail and by reference to illustrative embodiments thereof, it will be apparent that modifications and variations are possible without departing from the scope of the invention defined in the appended claims.

What is claimed is:

1. A computer-based method for validating clock signals in an integrated circuit comprising:
selecting one or more clock signals for validation;
specifying timing definitions of the selected clock signals;
automatically categorizing the selected clock signals based on their synchrony;
automatically matching each selected clock signal to a corresponding clock cycle by parsing the specified timing definitions;
specifying one or more test cases for an event simulator, wherein the test cases simulate logic for generating each selected clock signal; and
validating that the logic for generating each selected clock signal matches the specified timing definitions for each selected clock signal.

2. The method of claim 1, wherein said validating further comprises:
reading said one or more test cases into the event simulator;
executing said one or more test cases with the event simulator;
comparing a simulated waveform for each selected clock signal to the timing definitions for the selected clock signal;
determining whether the simulated waveform for each selected clock signal matches the timing definitions for the clock signal; and
in response to determining that the simulated waveform does not match the timing definitions, reporting an error to the user.

3. The method of claim 1, wherein the event simulator is capable of executing test cases encoded in a Tool Command Language (Tcl).

4. The method of claim 1, wherein said selecting further comprises excluding clock signals listed in an ignore file.

5. The method of claim 1, wherein said automatically matching further comprises:
determining a phase for each selected clock signal based on the specified timing definitions; and
mapping the phase to a primary input and a primary output of each selected clock signal.

6. The method of claim 1, wherein said timing definitions are imported from a static timing tool.

7. The method of claim 1, wherein said timing definitions include:
a pulse width;
a cycle time; and
an alignment to other synchronous clock signals.

8. A system for validating clock signals in an integrated circuit comprising:
a processor;
a memory;
means for selecting one or more clock signals for validation;
means for specifying timing definitions of the selected clock signals;
automatically categorizing the selected clock signals based on their synchrony;
means for automatically matching each selected clock signal to a corresponding clock cycle by parsing the specified timing definitions;
means for specifying one or more test cases for an event simulator, wherein the test cases simulate logic for generating each selected clock signal; and
means for validating that the logic for generating each selected clock signal matches the specified timing definitions for each selected clock signal.

9. The system of claim 8, wherein said means for validating further comprises:
means for reading said one or more test cases into the event simulator;
means for executing said one or more test cases with the event simulator;
means for comparing a simulated waveform for each selected clock signal to the timing definitions for the selected clock signal;
means for determining whether the simulated waveform for each selected clock signal matches the timing definitions for the clock signal; and
means, responsive to determining that the simulated waveform does not match the timing definitions, for reporting an error to the user.

10. The system of claim 8, wherein the event simulator is capable of executing test cases encoded in a Tool Command Language (Tcl).

11. The system of claim 8, wherein said means for selecting further comprises means for excluding clock signals listed in an ignore file.

12. The system of claim 8, wherein said means for automatically matching further comprises:
means for determining a phase for each selected clock signal based on the specified timing definitions; and
means for mapping the phase to a primary input and a primary output of each selected clock signal.

13. The system of claim 8, wherein said timing definitions are imported from a static timing tool.

14. The system of claim 8, wherein said timing definitions include:
a pulse width;
a cycle time; and
an alignment to other synchronous clock signals.

15. A computer-readable medium for validating clock signals in an integrated circuit, said computer-readable medium encoded with a computer program that, when executed causes a data processing system to perform the steps of:
selecting one or more clock signals for validation;
specifying timing definitions of the selected clock signals;
automatically categorizing the selected clock signals based on their synchrony;
automatically matching each selected clock signal to a corresponding clock cycle by parsing the specified timing definitions;
specifying one or more test cases for an event simulator, wherein the test cases simulate logic for generating each selected clock signal; and
validating that the logic for generating each selected clock signal matches the specified timing definitions for each selected clock signal.

16. The computer-readable medium of claim 15, wherein said validating further comprises:
reading said one or more test cases into the event simulator;
executing said one or more test cases with the event simulator;
comparing a simulated waveform for each selected clock signal to the timing definitions for the selected clock signal;
determining whether the simulated waveform for each selected clock signal matches the timing definitions for the clock signal; and
in response to determining that the simulated waveform does not match the timing definitions, reporting an error to the user.

17. The computer-readable medium of claim 15, wherein the event simulator is capable of executing test cases encoded in a Tool Command Language (Tcl).

18. The computer-readable medium of claim 15, wherein said automatically matching further comprises:
determining a phase for each selected clock signal based on the specified timing definitions; and
mapping the phase to a primary input and a primary output of each selected clock signal.

19. The computer-readable medium of claim 15, wherein said timing definitions are imported from a static timing tool.

20. The computer-readable medium of claim 15, wherein said timing definitions include:
a pulse width;
a cycle time; and
an alignment to other synchronous clock signals.
